(19) United States
(12) Patent Application Publication
(10) Pub. No.: US 2008/0065942 A1
(43) Pub. Date: Mar. 13, 2008

(54) Synthetic instrument utilizing peer-to-peer communication for error correction

(76) Inventor: Daniel Lee Pleasant, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/512,035

(22) Filed: Aug. 28, 2006

(51) Int. Cl. H04L 1/00; H03M 13/00; G08C 25/00; G06F 11/00; G06F 11/30

(52) U.S. Cl. 714/746

(57) ABSTRACT

An apparatus having a local network and a plurality of component modules is disclosed. Each component module has an input for receiving an input signal, an output for transferring an output signal derived from the input signal by that component module, and a network port that connects that module to the local network. A first component module introduces an error in the output signal derived by the first component module, the error causing that output signal to differ from an ideal output signal for that component module. The first component module communicates error information on the local network to a second component module, which alters its output signal to compensate for at least a portion of the error introduced by the first component module.

### BACKGROUND OF THE INVENTION

The hardware in electronics instruments that measure various physical parameters is not perfect. In many cases, the instruments can be calibrated and an algorithm provided that can be used to correct the raw data to provide a more accurate reading. For example, a spectrum analyzer may utilize an amplifier that has a gain that varies as a function of signal frequency, and hence, the amplitude measured at one frequency will be in error by an amount determined by the variation in amplifier gain. To compensate for such imperfections in the hardware, the hardware characteristics of an instrument are often measured before the instrument is used to measure the quantity of interest. The results of this calibration are then used to mathematically correct the data to provide a more accurate measurement of the desired quantity.

Originally, the corrections were performed after the data was recorded in a separate operation that often required a separate data processing system. As the cost of data processing systems has decreased, the error correction function has been incorporated in the instrument, and the error corrections are provided in real-time. These systems can also optimize the hardware during the measurement process to further reduce errors in the data. This approach has been successful with traditional instruments in which the measurement process from the collection of the raw data to the presentation of the final results is carried out in the same instrument.

However, there is a trend in the design of modern instruments to synthesize the instrument from a number of pre-existing component instruments. This approach allows the designer to upgrade one or more components without requiring a total instrument redesign. This approach is now being utilized to design the component instruments as well. In such instruments, none of the sub-systems has all of the information needed to correct all of the errors by itself.

In an attempt to overcome this problem, these “synthetic” instruments provide the error correction feature by incorporating a central controlling computer that performs the error correction and instrument optimization functions. In this approach, the central computer has knowledge of all of the hardware errors that are introduced by the measurement instruments and all of the optimization techniques that can be used to minimize the measurement errors. Before collecting data, the central computer adjusts the instrument's parameters to optimize the measurement, and after the data is collected, the central computer executes all of the error correction algorithms to provide the corrected data that is output to the user.

This approach has a number of problems, particularly when applied to a synthetic instrument in which the various components are not manufactured by the same manufacturer. First, some components utilize error correction algorithms that are internal to the hardware of that component. These error correction algorithms are often proprietary, and hence, the manufacturer of the component in question does not wish to reveal the algorithm to another vendor. Hence, the system designer must separately characterize each such component to determine the behavior of that component over the various signal ranges that are expected to be encountered in the synthetic instrument.

Second, this approach depends on a general-purpose data processor to provide the error corrections in question. In some cases, the error correction algorithms are more efficiently implemented on special purpose hardware such as digital signal processors or field-programmable gate arrays.

Third, if the instrument is redesigned by replacing one component with another that utilizes a different form of error correction, the software system on the general-purpose computer must also be redesigned to replace the optimization algorithms. This redesign can require that all of the error-correcting algorithms be reprogrammed, which significantly increases the cost and cycle time for such upgrades.

### SUMMARY OF THE INVENTION

The present invention includes an apparatus having a local network and a plurality of component modules. Each component module has an input for receiving an input signal, an output for transferring an output signal derived from the input signal by that component module, and a network port that connects that module to the local network. One of the component modules receives a signal that is external to the apparatus for processing on that component module's input port. The plurality of component modules includes first and second component modules. The first component module introduces an error in the output signal derived by the first component module, the error causing that output signal to differ from an ideal output signal for that component module. The first component module communicates error information on the local network to the second component module, which alters the output signal that would have been generated by the second component module in the absence of the error so as to compensate for at least a portion of the error introduced by the first component module. In one aspect of the invention, the first component module communicates information on the local network to the second component module that describes the nature of the error. In another aspect of the invention, one of said component modules sends data derived from the input signal to the second module on the local network. In another aspect of the invention, one of the component modules couples a signal present on the local network to an input of another of the component modules.

### BRIEF DESCRIPTION OF THE DRAWINGS

FIG. 1 illustrates a spectrum analyzer according to one embodiment of the present invention.

FIG. 2 illustrates another embodiment of a spectrum analyzer according to the present invention.

FIG. 3 illustrates one embodiment of an error-correction node according to the present invention.

### DETAILED DESCRIPTION OF EMBODIMENTS OF THE INVENTION

For the purposes of the present discussion, a synthetic instrument will be defined to be an instrument that processes an instrument input signal obtained from a device under test to arrive at an instrument output by applying a plurality of component modules to the input signal or signals derived therefrom. Each component module has a component input and a component output. The instrument input signal is applied to the component input of one of the component modules. The output of that component module can form the input of another component module and so on. The synthetic instrument can also include component modules that provide other inputs to one or more of the other component modules. In addition, the output of one or more of the modules could be a visual display. Finally, it should be noted that a component module could have a plurality of inputs and outputs, and these inputs and outputs could be digital, analog, or a combination of both digital and analog.

The sequence of input and output signals discussed above will be referred to as the signal path in the following discussion. This path can be a linear path consisting of the nodes between the component modules or a branched path. In addition to this signal path, the synthetic instrument includes a local network that connects some or all of the component modules. This network is used to communicate information that is generated by, or to be used by, one or more of the component modules. The information communicated on this network includes information and/or signals that are utilized in correcting errors introduced by one or more component modules.

For the purposes of the present discussion, an output signal leaving one of the modules in response to an input signal being coupled to the input of that module will be said to be in error if that output signal differs from the ideal output signal that would be generated by that module from that input signal. Consider two modules located on the signal path, and assume that the first module introduces errors into its output signal and that the second module is located down stream of the first module on the signal path. The errors introduced by the first module will cause the output of the second module, in general, to be in error in that the signal leaving the second module will differ from the signal that would have left the second module in the absence of the errors introduced by the first module even if the second module does not introduce any errors during its processing of its input signal.

For example, consider the simple case in which the second module operates directly on the output of the first module, the output of the first module is ten percent less than it should be, and the output of the second module is linearly related to the input to the second module. Then the second module can compensate for the errors introduced by the first module by increasing its output signal by ten percent relative to the signal that it would have generated in the absence of the error introduced by the first module. In essence, the second module introduces a new error that compensates for the error introduced by the first module.

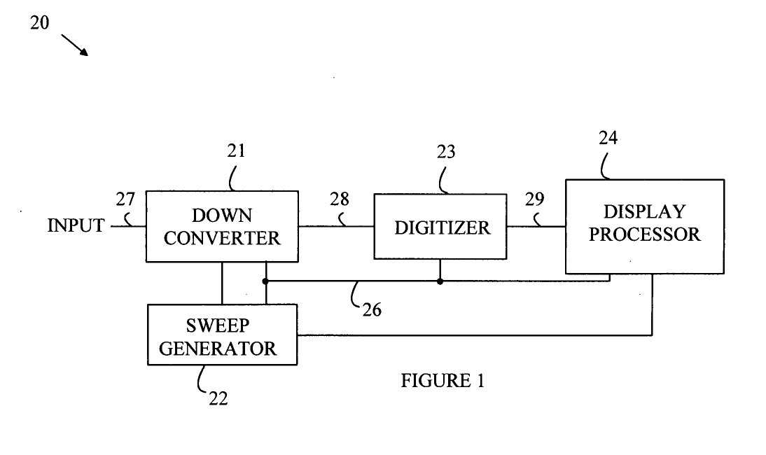

The manner in which the present invention provides its advantages can be more easily understood with reference to FIG. 1, which illustrates a spectrum analyzer according to one embodiment of the present invention. Spectrum analyzer 20 is constructed from four component modules, a down converter 21, a sweep generator 22, and a digitizer 23, and a display computer 24. The signal path corresponds to nodes 27-29. The down converter generates an analog signal that has an amplitude related to the amplitude of the input signal at the frequency currently input to the down converter by sweep generator 22. In this example, the sweep generator is controlled by display processor 24 over a separate connection. However, the control signals could also be provided over network 26 discussed below. The digitizer converts this analog signal to a digital form that is displayed by display processor 24. For the purposes of this example, it will be assumed that the signal generated by the down converter has an error that is a function of the sweep frequency and also the magnitude of the output signal. It will also be assumed that the output of the digitizer likewise has an error that is a function of the amplitude of the input signal to the digitizer.

In a prior art spectrum analyzer of this configuration, display processor 24 would have been responsible for correcting for these errors. Hence, the characteristics of down converter 21 and digitizer 23 would have been stored in display processor 24 and display processor 24 would have performed the corrections before displaying the data. This prior art approach requires display processor 24 to have sufficient computational capacity to apply the corrections in a time frame that is consistent with the real-time measurements being made. Furthermore, if down converter 21, digitizer 23, and display processor 24 are manufactured by different entities, the entities that manufacture down converter 21 and digitizer 23 must be agreeable to providing the error correcting strategies and profiles to the manufacturer of the display processor. In addition, if, for example, a new spectrum analyzer is to be constructed by replacing down converter 21 by a new down converter that introduces different errors, display processor 24 would need to be reprogrammed as part of the design process. Since display processor 24 is typically a general-purpose computer running a high-level operating system, this upgrade could involve a significant amount of work and lead time. In addition, the manufacturer of the two different analyzers would need to maintain two different sets of software for display processor 24.

The present invention overcomes these problems by providing a network over which the various components can communicate with one another and by implementing error correction in one or more of the components that are outside of the general purpose computer that normally controls the operations of the instrument. The network can be an internal network such as network 26 or an external network. To enable other components to participate in the error correction, the various components communicate information describing their error behavior on network 26. Hence, down converter 21 can communicate its error profile information to digitizer 23, which can then correct both for the errors introduced by down converter 21 and the errors generated within digitizer 23. The resultant corrected data can then be displayed by display processor 24 without that processor having knowledge of the error corrections. Hence, the error correction algorithms used within digitizer 23 can remain hidden. In addition, if down converter 21 is upgraded to a new device, the new device need only communicate its error profile to the digitizer, and hence, the software in display processor 24 does not require a revision.

It should be noted that other components could generate errors in addition to the components discussed above. For example, the sweep generator can also be a source of error. If the frequency generator by the sweep generator deviates from a linear function of time, the frequency values that are displayed to the user would be in error. These errors can be communicated and corrected in a manner analogous to that discussed above. For example, the sweep generator would send data to the digitizer that provides the errors to the digitizer where the frequency corresponding to the measured values would be adjusted to correct for these errors.

It should also be noted that the overall error correction could be distributed within the instrument. For example, down converter 21 could correct internally for gain errors that are a function of the input signal amplitude while leaving the correction of errors related to the local oscillator frequency to digitizer 23 or display processor 24.

The above-described embodiments depend on communication of error profile information between components within the instrument. In these embodiments, the actual data is communicated using peer-to-peer communications on network 26. The information exchange can take place during a calibration procedure or each time the instrument is powered up. Calibration procedures can be triggered by the user or automatically in response to some predetermined event such as the expiration of a specified time interval since the last calibration or a change in some environmental variable such as temperature. The information can be sent in response to a request by each device that performs error correction. Alternatively, each device that has an error correction profile can broadcast the data when requested or on power up.

In addition to the error correction information, information pertaining to the configuration of the component modules within the instrument must also be provided. For example, digitizer 23 needs to know that it is upstream on the signal path from down converter 21 so that digitizer 23 will know to utilize the error correcting information provided by down converter 21. This configuration information can be stored in one or more of the component modules and can be provided to all of the component modules in the same manner as the error correction information. In the example shown in FIG. 1, the configuration information is needed by digitizer 23 and, possibly, by display processor 24. The configuration information could be stored in these modules during the assembly of the instrument. Alternatively, display processor 24, for example, could store the instrument configuration and report that configuration on network 26.

The above-described embodiments depend on the individual instrument components having a standardized communication protocol and network interface. If the components are provided by different manufacturers, the standardization requirements can be even more severe. One method for avoiding this standardization process is to provide all or part of the error correction via a set of nodes that are inserted into the signal path and which are manufactured by a single vendor. While these nodes perform the specialized functions discussed below, it should be noted that one of these nodes is equivalent to a component module that performs certain specialized functions.

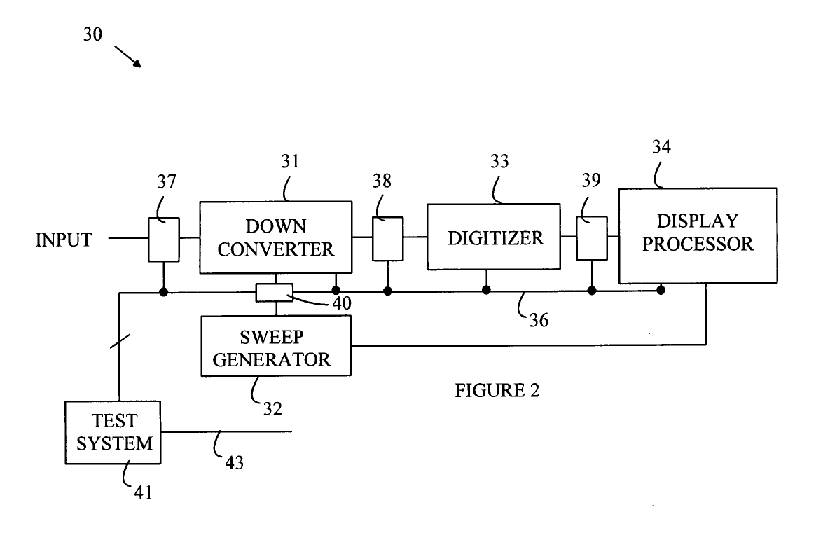

Refer now to FIG. 2, which illustrates another embodiment of a spectrum analyzer according to the present invention. Spectrum analyzer 30 is similar in operation to spectrum analyzer 20 discussed above. In particular, a down converter 31 is driven by a local oscillator from a sweep generator 32 to provide a signal that is digitized by digitizer 33 and displayed by display processor 34. Spectrum analyzer 30 avoids the standardization problem by utilizing a set of error correcting nodes 37-40 connected to network 36 to implement the error correcting protocols.

Each node can serve a number of functions. First, the nodes can be used to monitor the signals that pass through the nodes. The monitoring function can provide a means for calibrating the various components, since the signals can be measured both before and after the component has acted on the input signal. If the component has settings that can be accessed via network 36, a calibration computer can be used to optimize those settings by comparing the input and output signals monitored by the nodes on each side of the component in question and altering the settings to achieve the desired output signal.

Second, the nodes can be used to perform error correction functions. In this mode, the node intercepts the input signal and replaces it with a corrected signal. The node may include variable gain amplifiers, field programmable gate arrays, or other forms of signal processing. During a calibration phase, the node parameters can be optimized to correct for errors introduced by the component in question.

Third, the nodes can act as a source of input signals for testing and calibrating the instrument. The input signals could be generated in the node in question or coupled from network 36 through the node to the input of the desired component. In this regard, it should be noted that a test system 41 can be included in the instrument for testing and calibrating the instrument. In other embodiments, test system 41 can be external to the instrument and be connected during calibration and testing operations. In still other embodiments, part of test system 41 can be resident in the instrument with the remainder being external. The resident part of the test system can provide access to network 36 and the nodes over a second network 43 that could include the Internet. In such an embodiment, the instrument could be debugged or periodically calibrated by the vendor or a service provider utilizing equipment that is external to the instrument or even remote from the site at which the instrument resides.

The network used to communicate error-correcting data can include both analog and digital signals. The analog signal conductors can be utilized both to monitor analog signals and to provide test signals during testing and calibration. In one embodiment, the non-resident portion of the test system generates and analyzes the analog signals, and hence, a relatively complex testing and optimization program can be provided without substantially increasing the cost of the instrument.

In this regard, it should be noted that the software for characterizing the various signal components can be maintained as part of the test system, and this software can include modules specific to particular instrument components. For example, test system 41 can include a module for characterizing a down converter. The module in question would run down converter 31 while applying analog test signals to the input of down converter 31 via network 36 and node 37. Test system 41 can observe the output of down converter 31 by monitoring the output utilizing node 38. The software depends only on the input and output to a generic down converter. Hence, it can be utilized with a wide range of instruments having a down converter provided the instruments have the appropriate nodes and network connecting the nodes to the test system.

It should be noted that the test system, or a part thereof, could be located in one of the component modules. For example, digitizer 33 could include the hardware and software to correct for errors both in itself and in down converter 31. Furthermore, nodes 38 and 39 could be part of digitizer 33. In this case, digitizer 33 would receive the information characterizing down converter 31 either from down converter 31, an external test system during system calibration, or by applying signals to down converter 31 via node 37 and observing the resulting output. Digitizer 33 would then provide the corrections for the errors that arise from down converter 31 and itself.

The present invention can also be used to provide a distributed error correction capability to a synthetic instrument in which error correction features already developed for particular subsets of the components can be incorporated without significant changes in these error correction features. By reusing these components and their error correction features, the time needed to perfect a new instrument, including that instrument's error correction features could be substantially reduced. For example, consider the case in which digitizer 33 provides the error correction for itself and a generic down converter. If a new instrument having a down converter and digitizer 33 is constructed, then digitizer 33 can provide the error correction for that down converter and itself in a manner that is invisible to the controller in the new system, provided digitizer 33 can acquire the error correcting information for the new down converter. If the new instrument includes a node ahead of the new down converter, or the new down converter contains such a node, then digitizer 33 can obtain the information directly from the new down converter and provide error correction that is transparent to the overall system controller.

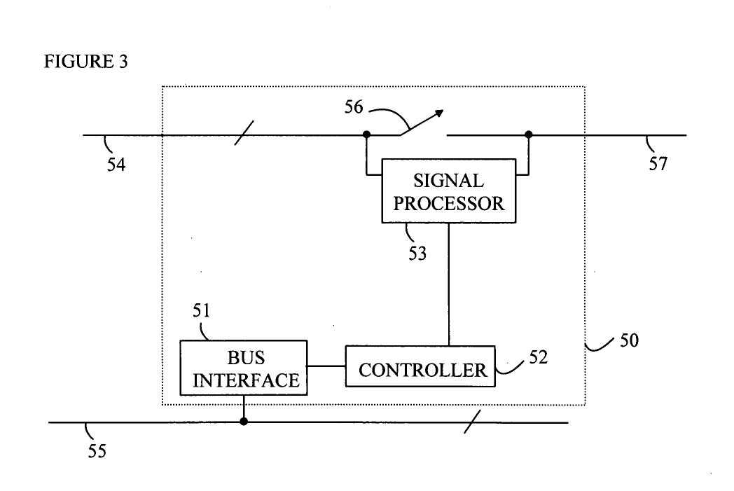

As noted above, the nodes can be part of the components from which the instrument is constructed, separate components introduced between components or a combination of both. Refer now to FIG. 3, which illustrates one embodiment of an error-correction node according to the present invention. Node 50 includes a bus interface 51 and controller 52. Bus interface 51 connects the node to an error correcting network that is implemented on a bus 55 that is similar to network 36 described above. Controller 52 monitors bus 55 for commands to which node 50 must respond and provides the response to those commands if needed. In one embodiment, controller 52 stores data describing the node and the device in which it resides. This data can include data describing the errors introduced by the device. Upon receiving an appropriate command, controller 52 sends a message on bus 55 with this data. Another device on the network can then use this data to correct for errors introduced by the component in question. If the node is not part of a component instrument, the data can include a description of the computational capabilities of the node and the types of signals that the node can handle.

In one embodiment, node 50 includes a signal processing and monitoring capability. Node 50 intercepts signals on input port 54 by opening switch 56, which is under the control of controller 52. Signal processor 53 transforms those signals to correct for errors introduced by one or more instrument components that are down stream of signal processor 53. The resulting corrected signals are output on output port 57. These components can include the component in which node 50 resides if node 50 is within one of the components. In addition, signal processor 53 can be utilized to monitor the signals on input port 54. If switch 56 is closed, node 50 merely monitors the signals and reports the data on bus 55 in response to a predetermined command. If switch 56 is open, signal processor 53 can provide information on the signals in question both before and after signal processor 53 has acted on the signals.

Signal processor 53 can also be used to introduce signals onto output port 57 for calibration, testing, or optimization purposes. The signals can be generated in response to a command on bus 55. The signals can be analog or digital in nature. The signals can be generated by controller 52 and signal processor 53. Alternatively, the signals can be coupled to node 50 on bus 55. The coupled signals can then be connected to bus 54 or stored in controller 52 to be used at another time.

As noted above, input port 54 can include multiple conductors for transferring both digital and analog signals. Similarly, output port 57 that connects the various component instruments can include multiple conductors that transfer both digital and analog signals.

While a general node would have such a multiconductor input and output port, specific nodes could have only a subset of these conductors. For example, the node that receives the output of the down converter described in FIG. 2 could include a single analog signal input port and output port.

Controller 52 can also download program code to be executed by signal processor 53 and/or controller 52. For example, signal processor 53 could be a field programmable gate array. In this case, the configuration code for performing a particular type of error correction or signal monitoring could be downloaded to signal processor 53 via controller 52.

The above-described embodiments utilized a separate test system. However, it should be noted that the test system can be viewed as a component module as well. In this regard, it should be noted that not all of the component modules in an instrument need to be connected directly to the signal path.

Various modifications to the present invention will become apparent to those skilled in the art from the foregoing description and accompanying drawings. Accordingly, the present invention is to be limited solely by the scope of the following claims.

What is claimed is:

1. An apparatus comprising:
a local network;
a plurality of component modules, each component module having an input for receiving an input signal, an output for transferring an output signal derived from said input signal by that component module, and a network port that connects that module to said local network, one of said component modules receiving a signal that is external to said apparatus for processing on that component module's input port,
wherein said plurality of component modules includes first and second component modules, wherein said first component module introduces an error in said output signal derived by said first component signal, said error causing that output signal to differ from an ideal output signal for that component module, and wherein said first component module communicates error information on said local network to said second component module, which alters said output signal that would have been generated by said second component module in the absence of said error so as to compensate for at least a portion of said error introduced by said first component module.

2. The apparatus of claim 1 wherein said first component module communicates information on said local network to said second component module that describes the nature of said error.

3. The apparatus of claim 1 wherein one of said component modules sends data derived from said input signal to that component module to another of said component modules on said local network.

4. The apparatus of claim 1 wherein one of said component modules couples a signal present on said local network to an input of another of said component modules.

5. The apparatus of claim 1 wherein one of said component modules comprises a test system for optimizing the performance of another of said component modules.

6. The apparatus of claim 1 wherein one of said component modules comprises a switch for connecting said input to said output of that component module.

7. The apparatus of claim 1 wherein one of said component modules comprises a signal processing unit connected between said input and said output of that component module, said signal processing unit being programmable by signals sent on said local area bus.

8. The apparatus of claim 1 wherein said local network communicates both analog and digital signals to and from said component modules.

9. The apparatus of claim 1 wherein one of said component modules stores information specifying the connections between said component modules in said apparatus and wherein that component module transmits that information to another of said component modules on said local network.

10. A method for correcting errors in an instrument having a plurality of component modules, each component module having an input for receiving an input signal, an output for transferring an output signal derived from said input signal by that component module, one of said component modules receiving a signal that is external to said method for processing on that component module's input port, said method comprising:
providing a local network connecting said component modules to one another;
causing a first component module to communicate error information describing an error in said output signal from said first component module to a second component module on said local network; and
causing said second component module to alter said output signal that would have been generated by said second component module in the absence of said error so as to compensate for at least a portion of said error introduced by said first component module.

11. The method of claim 10 wherein said error information describes the nature of said error.

12. The method of claim 10 further comprising causing one of said component modules to couple a signal present on said local network to an input of another of said component modules.

13. The method of claim 10 further comprising causing one of said component modules to optimize the performance of another of said component modules.

14. The method of claim 10 further comprising causing one of said component modules to connect said input of that component module to said output of that component module.
